(19) United States
(12) Patent Application Publication
(10) Pub. No.: US 2006/0044077 A1
(43) Pub. Date: Mar. 2, 2006

(54) Bias-feeding device

(75) Inventor: Hiroshi Ikeda, Tokyo (JP)

Correspondence Address: KANESAKA BERNER AND PARTNERS LLP, SUITE 300, 1700 DIAGONAL RD, ALEXANDRIA, VA, 22314-2848, US

(73) Assignee: TDK CORPORATION, Tokyo (JP)

(21) Appl. No.: 11/213,989

(22) Filed: Aug. 30, 2005

(30) Foreign Application Priority Data
Aug. 30, 2004 (JP) 2004-250734

(51) Int. Cl. H03H 7/00

(52) U.S. Cl. 333/181

(57) ABSTRACT

A bias-feeding device for feeding a bias signal to a physical object to be measured includes a first input terminal for inputting thereto a bias voltage, a second input terminal for inputting thereto a reference potential, a first output terminal for outputting the bias voltage to the physical object, a second output terminal for outputting the reference potential to the physical object, a first signal line for connecting the first input terminal and the first output terminal, a second signal line for connecting the second input terminal and the second output terminal, shielded from the first signal line, a first reactive element of a closed magnetic path structure inserted into the first signal line and a second reactive element of a closed magnetic path structure inserted into the second signal line.

### BACKGROUND OF THE INVENTION

1. Field of the invention

The present invention relates to a bias-feeding device for feeding a bias signal to a physical object to be measured.

2. Description of the Prior Art

Conventionally, a bias signal has been fed to a device under test (DUT) such as an active element including semiconductor elements or the like, for example, transistors etc., to measure the impedance and other parameters of the DUT. A measurement system of this kind comprises, as shown in FIG. 3, for example, a DUT 101, a network analyzer 102 for measuring the impedance and other parameters of the DUT 101, bias-T coaxial adapters 103₁, 103₂ for superimposing bias voltages in coaxial cables for measurement, via which the DUT 101 and the network analyzer 102 are connected to each other, and a bias power supply 104 for feeding a bias signal, which is connected to the bias-T coaxial adapters 103₁, 103₂.

What greatest attention is to be paid to in this kind of measurement is consolidated into suppression of oscillation. In this kind of measurement, however, since the frequency to be measured is a wide band, any frequency within a measurement range is in agreement with oscillation conditions and undesired oscillations are frequently induced. Particularly where a recently developed compound material semiconductor element is used as a DUT, since the frequency in use extends up to a millimeter waveband to make the measurement range extremely wide band, it becomes difficult to suppress oscillation. One of the causes of inducing such oscillation is that a part or all of signals on the output side of the DUT are fed back to the input side thereof or that the input side and the output side of the DUT are electrically coupled to each other via a signal line for feeding bias voltage or a ground line for feeding ground potential,

For the purpose of suppressing such oscillation, for example, the techniques disclosed in JP-A H11-17468 and JP-A 2000-304815 have been proposed.

Disclosed in JP-A H11-17468 is that a transistor provided with an input port and an output port is formed on a semiconductor substrate. Particularly, in this transistor, at least one of the input port and the output port is connected to absorption means which does not absorb signal components of the frequencies used in the transistor but absorbs frequency components having frequencies lower than that used in the transistor. To be specific, a coil is inserted into at least one of the input port and the output port of the transistor. Accordingly, with the transistor, it is assumed that such a parasitic oscillation phenomenon as occurred in a case of confirming the operation of a wafer can be prevented at the level of the circuits on the semiconductor substrate.

Disclosed in JP-A 2000-304815 is a device power source feeding apparatus for a semiconductor test device for applying a prescribed constant voltage to a power source terminal, an output terminal, an input terminal or a DUT terminal of a DUT, defined as an input or output terminal. To be specific, the device power source feeding apparatus is configured to be connected to the DUT via a cable equipped with a shield.

As described above, the causes of inducing oscillation is that a part or all of signals on the output side of the DUT are fed back to the input side thereof or that the input side and the output side of the DUT are electrically coupled to each other via a signal line for feeding bias voltage and a ground line for feeding ground potential.

With respect to the conditions from a viewpoint of alternative current, therefore, such oscillation can be suppressed by inserting a reactive element comprising a coil having a wire wound around a bobbin in a manner to cancel out the feedback capacitance as described in JP-A H11-17468 or by slightly shifting matching between the input side and the output side of the DUT at a oscillation frequency to reduce a gain.

The DUT, however, undesirably has a frequency selection property since using the reactive element comprising an ordinary coil or the matching network by these methods, so that those methods is in inapplicable at all to measure uniformly over a wide band, which is problematic. Particularly, in the case of the coil having a wire wound around a bobbin, since the reactive element has a capacitance between the wound wire parts and exhibits characteristics like those of a capacitor at frequency bands exceeding its self-resonant frequency point, thereby causing malfunctions.

Conversely, with respect to the conditions from a viewpoint of direct current, even where oscillation can be suppressed in alternative current, the power source and ground potential cannot be cut off where the input side and output side of the DUT are electrically coupled to each other via a signal line or ground line. Consequently, oscillation cannot be suppressed.

With the technique disclosed in JP-A 2000-304815, since a shield is merely provided between the power source and the DUT, it is also impossible to sufficiently suppress the electric coupling between the input side and the output side of the DUT.

The present invention has been accomplished in view of the state of affairs described above, and aims to provide a bias-feeding device capable of infallibly preventing electric coupling between the input side and the output side of a DUT without adversely affecting existing measuring systems and also capable of infallibly suppressing oscillation over a wide band.

### SUMMARY OF THE INVENTION

To attain the above object, a bias-feeding device according to this invention is such as feeding a bias signal to a physical object to be measured and comprises a first input terminal for inputting thereto a bias voltage, a second input terminal for inputting thereto a reference potential, a first output terminal for outputting the bias voltage to the physical object, a second output terminal for outputting the reference potential to the physical object, a first signal line for connecting the first input terminal and the first output terminal, a second signal line for connecting the second input terminal and the second output terminal, shielded from the first signal line, a first reactive element of a closed magnetic path structure inserted into the first signal line, and a second reactive element of a closed magnetic path structure inserted into the second signal line.

In the bias-feeding device according to the present invention, since the first signal line for feeding a bias voltage and the second signal line for feeding a reference potential are shielded from each other, it is possible to suppress as much as possible the connection between the first and second signal lines. In the bias-feeding device according to the present invention, furthermore, since a reactive element having such a closed magnetic path structure as inducing very small leakage of a magnetic flux is inserted into each of the first and second signal lines, both the first and second signal lines can be configured to exhibit high impedance at high frequencies and no loss from a viewpoint of direct current while configured not to be connected directly to the second signal line without connecting to each other the signal lines on the input and output sides of a physical object to be measured in the vicinity of the physical object. By using the bias-feeding device of the present invention for at least one of the input and output sides of the physical object, it is possible to infallibly prevent the electric coupling between the input and output sides of the physical object and to infallibly suppress the induction of oscillation.

Each of the first and second reactive elements can be configured using a ferrite bead or troidal core. It is particularly preferred that each of the first and second reactive elements be configured respectively in using at least two ferrite beads of different magnetic permeability between the first and second elements, a combination of at least one ferrite beans and a troidal core with different magnetic permeability between the first and second elements. To be specific, as the first and second reactive elements, elements respectively having different inductance values are preferably used. Thus, the bias-feeding device according to the present invention can be used for wide band measurements.

The bias-feeding device according to the present invention is equipped with a first shielded casing in which the first signal line is accommodated as inserted and a shielded second casing in which the second signal line is accommodated as inserted. As a result, the bias-feeding device according to the present invention can infallibly suppress the connection between the first and second signal lines.

Furthermore, it is preferred that the first and second output terminals are insulated from the first and second shielded casings, respectively, from a viewpoint of alternative current.

Moreover, the first output terminal can be configured as a central terminal for connecting a coaxial cable, and the second output terminal can be configured as an outer terminal for connecting the coaxial cable. Thus, the bias-feeding device according to the present invention can be connected via the coaxial cable to a physical object to be measured and is therefore excellent in versatility.

It is to be noted that as the physical object to be measured, an active element can be applied. The bias-feeding device according to the present invention is advantageously used for measurement of the impedance and/or other parameters of the active element. That is to say, with a measurement system to which the bias-feeding device of the present invention is applied, undesirable oscillation can infallibly be suppressed, with the result that the impedance and other parameters of the active element can be measured with high precision and that breakage of the active element and measurement equipment resulted from the oscillation can be prevented from occurring.

According to the present invention, therefore, the electric coupling through first and second signal lines between the input and output sides of a physical object to be measured can infallibly be prevented to infallibly suppress oscillation.

The above and other objects, characteristic features and advantages of the present invention will become apparent to those skilled in the art from the description given herein below with reference to the accompanying drawings.

### BRIEF DESCRIPTION OF THE DRAWINGS

FIG. 1 is a block diagram illustrating the configuration of a measurement system to which a bias-feeding device of one embodiment according to the present invention is applied.

FIG. 2 is an explanatory view showing the configuration of a concrete circuit of the bias-feeding device of the embodiment according to the present invention.

FIG. 3 is a block diagram illustrating the configuration of a conventional measurement system.

### DETAILED DESCRIPTION OF THE PREFERRED EMBODIMENT

The present invention will be described hereinafter with reference to an embodiment thereof shown in the accompanying drawings.

In this embodiment, an active element including semiconductor elements such, e.g., as transistors etc. or a device under test (DUT) such as, e.g., amplifiers using the active element, is defined as a physical object to be measured. With a measurement system in which a bias signal is fed to the physical object to measure the impedance and/or other parameters of the physical object, a bias-feeding device of the present invention is provided between a power source and the physical object. In particular, this bias-feeding device can infallibly prevent the electric coupling between input and output sides of the physical object through a signal line for feeding a bias voltage or a ground line for feeding a ground potential defined as a reference potential and can infallibly suppress induction of oscillation over a wide band.

Specifically, the measurement system comprises, as shown in FIG. 1, a network analyzer 2 for measuring the impedance or other parameters of a DUT 1, bias-T coaxial adapters 3₁, 3₂ for superimposing bias voltages in coaxial cables for measurement for connecting the DUT 1 to the network analyzer 2, a bias power supply 4 for supplying a bias signal, and a bias-feeding device 5 provided among the bias power supply 4 and the bias-T coaxial adapters 3₁, 3₂.

This measurement system is configured in a manner to feed a bias signal supplied from the bias power supply 4 via the bias-T coaxial adapters 3₁, 3₂ to the DUT 1 to measure the impedance and other parameters of the DUT 1 using the network analyzer 2. In this measurement system, to prevent the electric coupling through the signal line or ground line between the input and output sides of the DUT 1, the bias signal supplied from the bias power supply 4 is fed to the DUT 1 not directly but via the bias-feeding device 5.

The bias-feeding device 5 is configured to satisfy at least three conditions (1) that both the signal line for feeding the bias voltage from the bias power supply 4 and the ground line for feeding the ground potential exhibit high impedance from a viewpoint of high frequency and no loss from a viewpoint of direct current (2) that the ground lines on the input and output sides of the DUT 1 are not connected to each other in the vicinity of the DUT 1 and are not directly connected to the ground line of the bias power supply 4 and (3) that the signal lines are suppressed as much as possible from being electrically coupled to one another.

To be specific, the bias-feeding device 5 has a reactive element with such a closed magnetic path structure as inducing very small leakage of a magnetic flux, differently from an ordinary coil having a wire wound around a bobbin, inserted into each signal line to satisfy the condition (1). As the reactive element of closed magnetic path structure, a ferrite bead and/or an element having a wire wound around a troidal core can advantageously be used. The ferrite bead is an element having a structure in which a signal line for electric flow can be inserted into the inside of a ferrite element. The ferrite element serves as a magnetic substance to absorb high-frequency components while it has a low resistance property from a viewpoint of direct current because it has an ordinary signal line inserted therein. The troidal core is an element which comprises a donut-shaped core member made of a prescribed metal sintered at high temperatures and which is used in a state where a signal line is wound around the donut-shaped core member. In the bias-feeding device 5, at least two ferrite beads of different magnetic permeabilities, an element having a wire wound around at least two troidal cores of different magnetic permeabilities, or a combination of those ferrite beads and element having a wire wound around the troidal core are/is desirably used in order to make it possible to perform wide band measurements. That is to say, in the bias-feeding device 5, by using elements of different inductance values, measurement can be made over a wide band. Particularly for the bias-feeding device 5, in selecting elements of different inductance values, it is desirable to take into consideration the influence of the self-resonant point so that measurement can uniformly be made over the frequency bands within the range of measurement.

Thus, in the bias-feeding device 5, by inserting the reactive element of closed magnetic path structure into each signal line, both the signal line for feeding the bias voltage from the bias power supply 4 and the ground line for feeding the ground potential can be configured to exhibit high impedance from a viewpoint of high frequency and no loss from a viewpoint of direct current.

To satisfy the condition (2), in the bias-feeding device 5, the terminals on the side of the DUT 1, i.e. on the output side, are insulated from a box body forming the contour of the bias-feeding device 5 and also from the paired terminals on the input side in alternative current. To be specific, in the bias-feeding device 5, the output side terminals are insulated with a prescribed insulating material from the box body. Also in the bias-feeding device 5, the reactive element of closed magnetic path structure is inserted between the output side terminals and the input side terminals to obtain a configuration exhibiting a low resistance property from a viewpoint of direct current, but a high resistance property from a viewpoint of alternative current.

Thus, in the bias-feeding device 5, the terminal on the side of the DUT 1 is insulated from the box body forming the contour of the bias-feeding device 5 and also from the paired terminal on the input side. As a result, the ground lines on the input and output sides of the DUT 1 are not connected in the vicinity of the DUT 1 and can be configured so that they may not be directly connected to the ground line of the bias power supply 4. Thus, it is possible to avoid part or all of the signals on the output side of the DUT 1 being fed back to the input side.

To satisfy the condition (3), the bias-feeding device 5 has a structure in which signal lines are independently shielded from one another. Specifically, in the bias-feeding device 5, a casing is formed in the bias-feeding device 5 so that each of the signal lines is shielded from one another. The casing is such as made of prescribed metal body subject to cutting, composing the box body, such as, e.g., aluminum, brass, or the like, in which each of the signal lines is accommodated as inserted independently, or such as having prescribed metal plates disposed among the signal lines.

Thus, the bias-feeding device 5 is configured to shield each of signal lines from one another, thereby being able to suppress as much as possible each of the signal lines from electric coupling with one another, so that the measurable frequency bands can become wider.

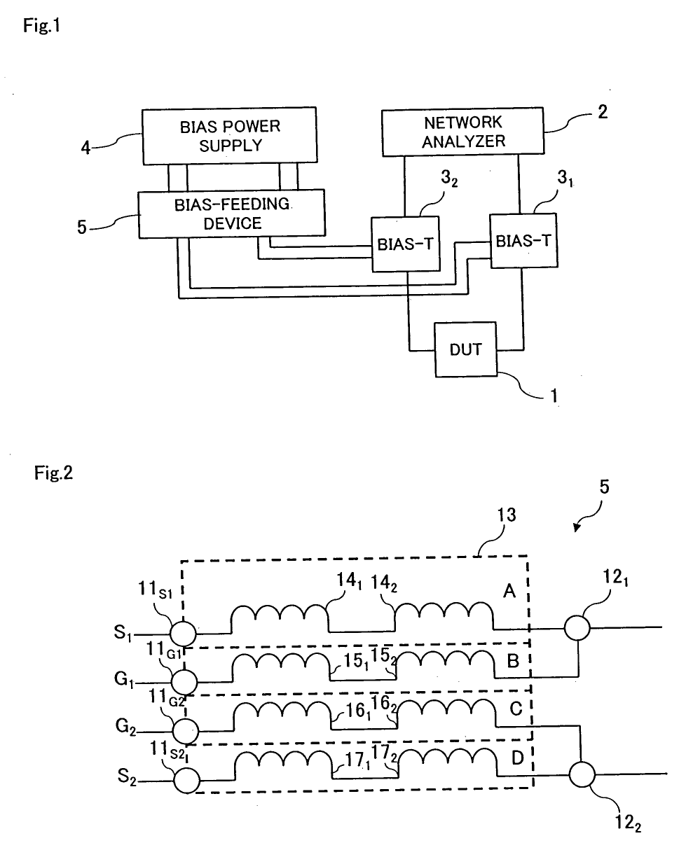

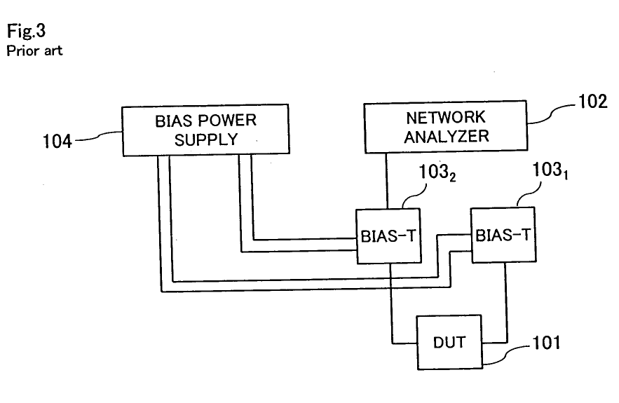

The bias-feeding device 5 satisfying the abovementioned three conditions can be realized by a circuit configuration shown in FIG. 2.

To be specific, in the bias-feeding device 5, as input terminals inputting bias signals supplied from the bias power supply 4, a bias terminal 11_{S1} that is a first input terminal inputting bias voltage S₁, a ground terminal 11_{G1} that is a second input terminal inputting ground potential G₁, a bias terminal 11_{S2} inputting bias voltage S₂ and a ground terminal 11_{G2} inputting ground potential G₂ are provided in a box body 13 made of a prescribed metal. Also in the bias-feeding device 5, as output terminals outputting bias signals to the DUT 1, an output terminal 12₁ that is first and second output terminals corresponding respectively to the bias terminal 11_{S1} and ground terminal 11_{G1} and an output terminal 12₂ that is third and fourth output terminals corresponding respectively to the bias terminal 11_{S2} and ground terminal 11_{G2} are provided in the box body 13 in a state where those the output terminals 12₁, 12₂ are insulated from the box body 13. Incidentally, in FIG. 2, the output terminals 12₁, 12₂ are configured as terminals to which a coaxial cable is connected, wherein signal lines extending from the bias terminals 11_{S1}, 11_{S2} are connected respectively to the central terminals of the output terminals 12₁, 12₂, and signal lines extending from the ground terminals 11_{G1}, 11_{G2} are connected respectively to the outer terminals of the output terminals 12₁, 12₂.

Also, in the bias-feeding device 5, four signal lines, i.e. a signal line connecting the bias terminal 11_{S1} to the output signal 12₁, a signal line connecting the ground terminal 11_{G1} to the output terminal 12₁, a signal line connecting the bias terminal 11_{S2} to the output terminal 12₂ and a signal line connecting the ground terminal 11_{G2} to the output terminal 12₂, are accommodated in independent casings A, B, C and D partitioned respectively with prescribed metal plates and are thus shielded from one another.

Also in the bias-feeding device 5, reactive elements 14₁, 14₂ of closed magnetic path structure comprising ferrite beads, troidal core, etc. are inserted into the signal line accommodated in the casing A, reactive elements 15₁, 15₂ of closed magnetic path structure are inserted into the signal line accommodated in the casing B, reactive elements 16₁, 16₂ are inserted into the signal line accommodated in the casing C, and reactive elements 17₁, 17₂ are inserted into the signal line accommodated in the casing D. While FIG. 2 shows the case where two reactive elements are inserted into each signal line, the kind and number of reactive elements can be determined in the bias-feeding device 5 depending on the frequency bands within the measurement range.

As has been described in the foregoing, according to the bias-feeding device 5 illustrated as the embodiment of the present invention, electric coupling between the input and output sides of the DUT 1 via the signal lines for feeding the bias voltage from the bias power supply 4 and the ground lines for feeding the ground potential can be prevented with exactitude. In the measurement system, therefore, by disposing the bias-feeding device 5 between the bias power supply 4 and the DUT 1, oscillation can infallibly be suppressed without adversely affecting the existing measurement systems. Particularly, in the measurement system, by appropriately selecting reactive elements to be inserted into the signal lines of the bias-feeding device 5, wide band measurement over multioctave bands from several MHz bands to several tens GHz bands can be performed. Therefore, in a measurement system to which the bias-feeding device 5 of the present invention is applied, undesirable oscillation can be suppressed with exactitude, the impedance and other parameters of the DUT 1 can be measured with high precision, and breakage of the measurement equipments including the DUT 1 and the network analyzer 2 resulting from the oscillation can be prevented from occurring.

The present invention is not limited to the embodiment as described above. Though the embodiment has been described in which the coaxial cable is used as a cable connecting the bias-feeding device 5 to the DUT 1, for example, an optional cable is applicable to the present invention insofar as it can feed bias signals.

Also, the embodiment of the present invention is described, wherein the paired bias terminals and paired ground terminals are provided as the input terminals inputting bias signals supplied from the bias power supply 4 and wherein the paired output terminals are provided. However, the present invention may have a configuration without sticking to the number of these terminals, in which at least a bias terminal for inputting bias voltage and a ground terminal for inputting ground potential that are the input terminals and an output terminal corresponding to the bias and ground terminals are provided.

Thus, it goes without saying that the present invention can appropriately be modified within a range not departing from the gist of the present invention.

What is claimed is:

1. A bias-feeding device for feeding a bias signal to a physical object to be measured, comprising:
a first input terminal for inputting thereto a bias voltage;
a second input terminal for inputting thereto a reference potential;
a first output terminal for outputting the bias voltage to the physical object;
a second output terminal for outputting the reference potential to the physical object;
a first signal line for connecting the first input terminal and the first output terminal;
a second signal line for connecting the second input terminal and the second output terminal, shielded from the first signal line;
a first reactive element of a closed magnetic path structure inserted into the first signal line; and
a second reactive element of a closed magnetic path structure inserted into the second signal line.

2. A bias-feeding device according to claim 1, wherein each of the first and second reactive elements is configured using a ferrite bead or troidal core.

3. A bias-feeding device according to claim 1, wherein each of the first and second reactive elements is configured using at least two ferrite beads of different magnetic permeabilities.

4. A bias-feeding device according to claim 1, wherein each of the first and second reactive elements is configured using a combination of at least one ferrite beads and a troidal core of different magnetic permeabilities.

5. A bias-feeding device according to claim 1, further comprising a first shielded casing for accommodating as inserting the first signal line and a second shielded casing for accommodating as inserting the second signal line.

6. A bias-feeding device according to claim 5, wherein the first and second output terminals are insulated from the first and second shielded casings in alternative current.

7. A bias-feeding device according to claim 1, wherein the first output terminal is defined as a central terminal for connecting a coaxial cable, and the second output terminal is defined as an outer terminal for connecting the coaxial cable.

8. A bias-feeding device according to claim 1, wherein the physical object is defined as an active element and the bias-feeding device is used for measurement of impedance and/or other parameters of the active element.
